(19) United States
(12) Patent Application Publication
(10) Pub. No.: US 2018/0246173 A1
(43) Pub. Date: Aug. 30, 2018

(54) ONLINE DETERMINATION OF MODEL PARAMETERS OF LEAD ACID BATTERIES AND COMPUTATION OF SOC AND SOH

(71) Applicant: HONEYWELL INTERNATIONAL INC., Morris Plains, NJ (US)

(72) Inventors: Harmohan N. Singh, Rockaway Township, NJ (US); Jeevan Reddy Neelam, Bangalore (IN); Madasamy Shunmugavel, Bangalore (IN)

(73) Assignee: HONEYWELL INTERNATIONAL INC., MORRIS PLAINS, NJ (US)

(21) Appl. No.: 15/444,728

(22) Filed: Feb. 28, 2017

(51) Int. Cl. G01R 31/36

(52) U.S. Cl. CPC G01R 31/3651; G01R 31/3662; G01R 31/3679

(57) ABSTRACT

Methods and apparatus for online estimation of battery model parameters for determining a State-of-Charge (SoC) and a State-of-Health (SoH) of a battery are provided. A mathematical approach using voltage, current, and temperature samples at programmable intervals to estimate RC battery model parameters is utilized, reducing computational requirements to enable real-time estimation of the SoC in an online environment. The SoC estimation utilizes an optimal estimator with an Extended Kalman Filter (EKF) to reduce sensitivity to process noise and measurement errors. After a discharge or charge operation, the SoH can also be estimated and updated as necessary.

### BACKGROUND OF THE INVENTION

The present invention generally relates to apparatus and methods for determining battery SoC (State of Charge) and SoH (State of Health). More particularly, the present invention relates to apparatus and methods for online determination of model parameters of batteries and computation of SoC and SoH.

Batteries such as lead acid batteries are one of the most widely used power sources for automotive applications, providing the power for starting, lighting, and ignition. In addition, lead acid batteries are used for transmission power in electric and hybrid vehicles. To provide sufficient power to crank an automotive engine, the lead acid battery is usually designed with a large number of thin plates to provide a large surface area for maximizing current output. However, irreversible damage may occur in this thin plate design when a deep discharge operation occurs. To avoid deep discharge operations, it is necessary to know the state of the battery, which can be expressed in terms of SoC.

SoC, expressed in percentage, represents a charge left in a battery. Since SoC cannot be calculated directly, accurate SoC estimation is one of the prevailing problems to be solved in the industry. An accurate SoC estimation allows the battery to be used to its full potential, increasing battery life, performance, and reliability. Additionally, in a hybrid vehicle, a more accurate SoC estimation enables the vehicle's main computer to switch a power source between the battery and the internal combustion (IC) engine to avoid deep discharge more reliably.

SoH is a number that describes the condition of the battery. Thus, the SoH provides information on a battery's ability to store and deliver energy when compared to a new battery. From a user's perspective, an accurate SoH measurement provides helpful advance warning regarding the maintenance and replacement of batteries. From a manufacturer's perspective, an accurate SoH measurement enables informed business decisions concerning service and warranty commitments.

Similar to SoC, SoH cannot be calculated directly. Accordingly, SoC and SoH estimations often utilize a model based approach to determine the parameters of the battery based on a model of the battery. Once the parameters are known, then the parameters can be utilized to estimate the SoC and SoH.

Known model based approaches for estimating battery parameters suffer from several drawbacks. First, existing approaches often require large computational time and/or memory footprint. For an online application where the battery is in use and calculation must be performed in real-time, computational efficiency becomes a primary concern. Second, particular battery parameters may vary from battery to battery and according to battery usage and calendar life. Existing approaches may characterize batteries using a one-size fits all approach that does not consider the manufacture characteristics and battery wear state for each individual battery.

As can be seen, there is a need for apparatus and methods for an accurate determination of model parameters of batteries and computation of SoC and SoH that is also suitable for an online environment.

### SUMMARY OF THE INVENTION

In one aspect of the present invention, a method for online estimation of battery model parameters for determining a State-of-Charge (SoC) of a battery is provided, the method comprising: initiating an operation on the battery, the operation comprising one of a charge and a discharge; estimating a series ohmic resistance (R_{S}) based on a voltage change divided by a current change at a starting instant of the operation; updating a temperature coefficient (a₀) based on a temperature of the battery and the SoH determined from the R_{S}; performing, until the operation on the battery is completed: for each of a plurality of updating intervals: for each of a plurality of sampling intervals: updating a sample of the battery, wherein the sample includes a voltage, a current, and a temperature; estimating the SoC using ampere hour (Ah) counting of the sample; updating a series ohmic resistance (R_{S}) of the battery based on the temperature coefficient and the estimated SoC; computing a RC model voltage (V₀) across a RC circuit of the battery, a RC model resistance (R₀) of the battery, and a RC model capacitance (C₀) of the battery, wherein the V₀ is a polarization voltage derived based on the voltage and the current of the sample, the updated R_{S}, and a Peukert's constant for the battery; estimating and updating the R₀ and the C₀ using a polarization voltage curve constructed from the V₀ of the plurality of sampling intervals; estimating and updating the SoC using an optimal estimator with inputs comprising the sample, the R_{S}, the R₀, and the C₀.

In another aspect of the present invention, an apparatus is provided for online estimation of battery model parameters for determining a State-of-Charge (SoC) of a battery, the apparatus comprising one or more processors configured to: initiate an operation on the battery, the operation comprising one of a charge and a discharge; estimate a series ohmic resistance (R_{S}) based on a voltage change divided by a current change at a starting instant of the operation; update a temperature coefficient (a₀) based on a temperature of the battery and the SoH determined from the R_{S}; and perform, until the operation on the battery is completed: for each of a plurality of updating intervals: for each of a plurality of sampling intervals: update a sample of the battery, wherein the sample includes a voltage, a current, and a temperature; estimate the SoC using ampere hour (Ah) counting of the sample; update a series ohmic resistance (R_{S}) of the battery based on the temperature coefficient and the estimated SoC; compute a RC model voltage (V₀) across a RC circuit of the battery, a RC model resistance (R₀) of the battery, and a RC model capacitance (C₀) of the battery, wherein the V₀ is a polarization voltage derived based on the voltage and the current of the sample, the updated R_{S}, and a Peukert's constant for the battery; estimate and update the R₀ and the C₀ using a polarization voltage curve constructed from the V₀ of the plurality of sampling intervals; estimate and update the SoC using an optimal estimator with inputs comprising the sample, the R_{S}, the R₀, and the C₀.

In a further aspect of the present invention, a computer readable non-transitory medium is provided for online estimation of battery model parameters for determining a State-of-Charge (SoC) of a battery, the computer readable non-transitory medium storing one or more instructions that, when executed by one or more processors, causes: initiating an operation on the battery, the operation comprising one of a charge and a discharge; estimating a series ohmic resistance (R_{S}) based on a voltage change divided by a current change at a starting instant of the operation; updating a temperature coefficient (a₀) based on a temperature of the battery and the SoH determined from the R_{S}; performing, until the operation on the battery is completed: for each of a plurality of updating intervals: for each of a plurality of sampling intervals: updating a sample of the battery, wherein the sample includes a voltage, a current, and a temperature; estimating the SoC using ampere hour (Ah) counting of the sample; updating a series ohmic resistance (R_{S}) of the battery based on the temperature coefficient and the estimated SoC; computing a RC model voltage (V₀) across a RC circuit of the battery, a RC model resistance (R₀) of the battery, and a RC model capacitance (C₀) of the battery, wherein the V₀ is a polarization voltage derived based on the voltage and the current of the sample, the updated R_{S}, and a Peukert's constant for the battery; estimating and updating the R₀ and the C₀ using a polarization voltage curve constructed from the V₀ of the plurality of sampling intervals; estimating and updating the SoC using an optimal estimator with inputs comprising the sample, the R_{S}, the R₀, and the C₀.

These and other features, aspects and advantages of the present invention will become better understood with reference to the following drawings, description and claims.

### BRIEF DESCRIPTION OF THE DRAWINGS

FIG. 1 is a block diagram of an exemplary battery powered system utilizing online estimation of State-of-Charge (SoC), according to an exemplary embodiment of the present invention;

FIG. 2 is a circuit diagram of an exemplary 1-RC battery model;

FIG. 3 is an exemplary graph for estimating a series ohmic resistance of a battery by using a voltage and current profile of a discharging operation;

FIG. 4 is an exemplary graph for estimating model parameters of a battery by using a voltage and current profile of a discharging operation;

FIG. 5 is an exemplary graph of a battery voltage curve demonstrating a voltage profile due to battery dynamics;

FIG. 6A and FIG. 6B are flowcharts of an exemplary method for online estimation of battery parameters for determining a State-of-Charge (SoC) of a battery.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Various inventive features are described below that can each be used independently of one another or in combination with other features.

Broadly, this invention relates to online estimation of battery parameters for determining a State-of-Charge (SoC) and a State-of-Health (SoH) of a battery. By utilizing a streamlined mathematical approach using voltage, current, and temperature samples to estimate 1-RC battery model parameters, computational requirements are reduced to enable real-time estimation of the SoC in an online environment. No lengthy look-up tables are required to be stored, reducing memory footprint. The SoC estimation utilizes an optimal estimator with an Extended Kalman Filtering (EKF) to reduce sensitivity to process noise and measurement errors. After a discharge or charge operation, the SoH can also be estimated and updated as necessary. While the examples illustrated herein are for a lead acid battery, the SoC and SoH estimation can also apply to any battery chemistry that can be modeled using a RC model.

The technical problem of improving the performance, reliability, maintenance and diagnostics of battery technology is solved by the technical solution of accurately estimating the SoC and SoH of a battery while in an online environment, as described herein. An accurate estimate of battery parameters allows a vehicle to better manage the battery, for example by setting thresholds according to the estimated SoC and SoH to avoid deep discharge operations that could adversely affect the battery. In a hybrid vehicle, for example, a power source may be switched from the battery to an internal combustion engine if the threshold is crossed. Further, as described above in the background, an accurate SoC and SoH also enables useful maintenance notifications for end users and allows battery manufacturers to better tailor their warranties and customer service commitments.

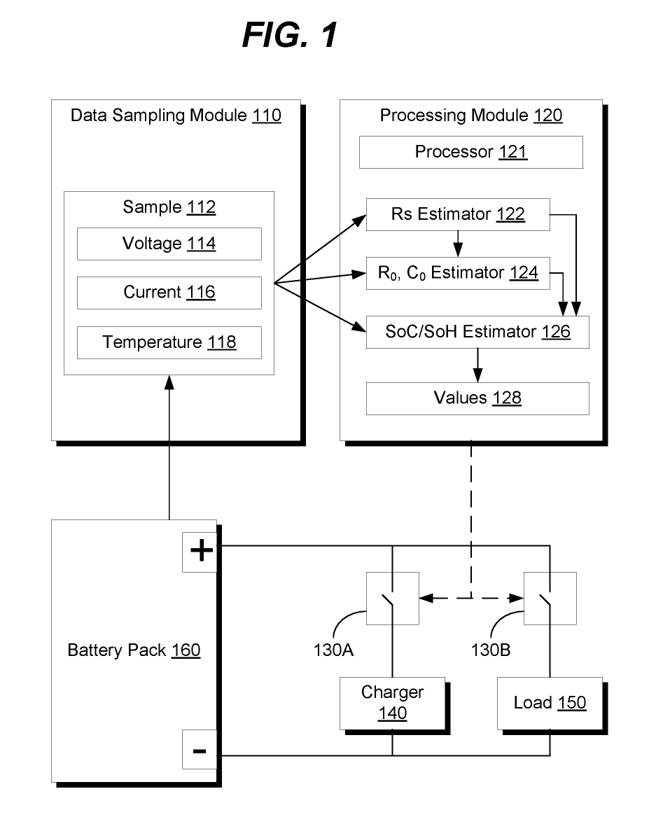

Before discussing the particulars of the mathematical approach, a broad overview of a battery powered system may be helpful to provide background context. Accordingly, FIG. 1 is a block diagram of an exemplary battery powered system utilizing online estimation of State-of-Charge (SoC), according to an exemplary embodiment of the present invention. FIG. 1 includes data sampling module 110, processing module 120, contactor 130A, contactor 130B, charger 140, load 150, and battery pack 160. Data sampling module 110 includes sample 112. Sample 112 includes voltage 114, current 116, and temperature 118. Processing module 120 includes processor 121, Rs estimator 122, R₀C₀ estimator 124, SoC/SoH estimator 126, and values 128.

Processor 121 may include one or more general purpose or customized processors in any suitable configuration, including a microprocessor, a microcontroller, a system on chip, and others. Rs estimator 122, R₀C₀ estimator 124, SoC/SoH estimator 126 may be implemented using any combination of software and hardware, which may include computer readable instructions, stored on a non-transitory computer readable medium, for execution by processor 121.

Battery pack 160 may include one or more battery cells connected in series and/or in parallel combination. Battery pack 160 is a lead acid battery in this particular example, but battery pack 160 may utilize any battery chemistry that can be modeled using a RC model. Charger 140 is used for charging battery pack 160, and load 150 is used for discharging battery pack 160. For example, charger 140 may correspond to the generator connected to engine shaft or power received from regenerative braking of a vehicle, and load 150 may correspond to an electric motor used for cranking the engine or an electric motor for acceleration of the electric vehicle.

Processing module 120 may begin with processor 121 initiating a charging or discharging operation on battery pack 160. If a charging operation is required, e.g. power available from generator connected to engine shaft or due to a user applying brakes to a vehicle, then processor 121 may direct contactor 130A to be closed and contactor 1308 to be opened to allow charger 140 to charge battery pack 160. Similarly, if a discharging operation is required, e.g. for cranking the engine or due to the user applying an acceleration pedal to the electric vehicle, then processor 121 may direct contactor 130A to be opened and contactor 130B to be closed to allow load 150 to discharge battery pack 160. Processor 121 may also direct a power source to be switched between battery pack 160 and an alternative energy source, such as an internal combustion engine or a different battery pack.

Once the charging or discharging operation is initiated, then data sampling module 110 may collect a sample 112 at regular periodic intervals, for example by using sensors or other components. This regular periodic interval may be set according to required granularity and memory constraints, among other considerations. As shown in FIG. 1, sample 112 includes voltage 114, current 116, and temperature 118, which may correspond to sampled voltage, current, and temperature values of battery pack 160 at a particular time.

Sample 112 may then be utilized to estimate values 128 using a programmable update interval. Note that this estimation update interval does not have to be the same as the sampling interval for sample 112. Accordingly, the sampling intervals for sample 112 may occur more frequently than the estimation intervals for values 128. Values 128 may include, among other values, Rs, R₀, C₀, SoC, and SoH. As shown in FIG. 1, Rs estimator 122, R₀C₀ estimator 124, and SoC/SoH estimator 126 may use sample 112 as an input. Further, R₀C₀ estimator 124 may use the output of Rs estimator 122 as an input, and SoC/SoH estimator 126 may use the outputs of Rs estimator 122 and R₀C₀ estimator 124 as inputs. Once values 128 are obtained, then the SoC and SoH values can be used to help prevent deep discharge of battery pack 160, for example by switching from battery to engine power if the SoC falls under a certain threshold. The SoC and SoH may also be recorded and reported for maintenance and diagnostic purposes.

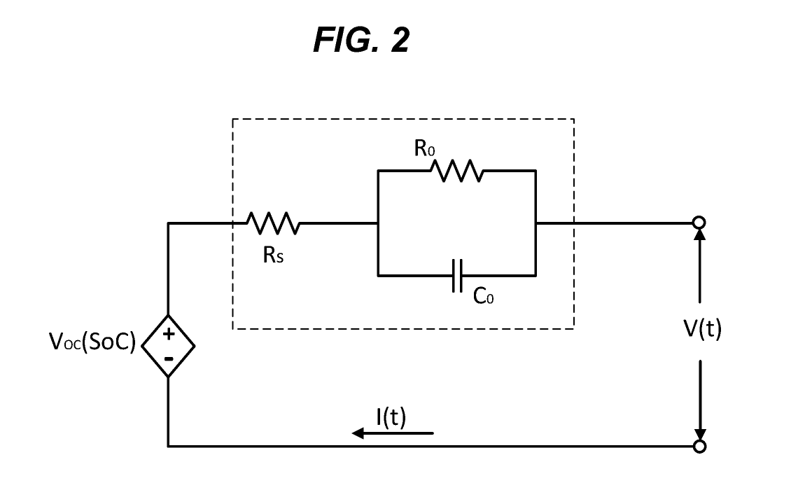

As discussed above, since SoC and SoH cannot be calculated directly, a model approach is often utilized to estimate the SoC and SoH according to a model of the battery. Accordingly, FIG. 2 is a circuit diagram of an exemplary 1-RC battery model. The battery model includes a dependent voltage source “OCV(SoC)”, also referred to as “Voc(SoC)”, a series resistance (Rs), and a one RC or 1-RC circuit (R₀, C₀). OCV(SoC) represents a relationship between the SoC and the OCV (rested open circuit voltage) of the battery, Rs represents the series ohmic resistance, and R₀, C₀ represents the effects of dynamics observed in lead acid batteries.

The battery model parameters Rs, R₀, and C₀ vary according to SoC, temperature, and battery age. In particular, Rs varies significantly with SoC, temperature, and battery aging. As shown in FIG. 1, the output of Rs estimator 122 is used as an input for SoC/SoH estimator 126. Thus, to provide an accurate estimation of SoC and SoH, it is desirable to perform an online estimation of Rs in order to factor in the current temperature, SoC, and battery wear level.

### Series Ohmic Resistance (Rs) Estimation

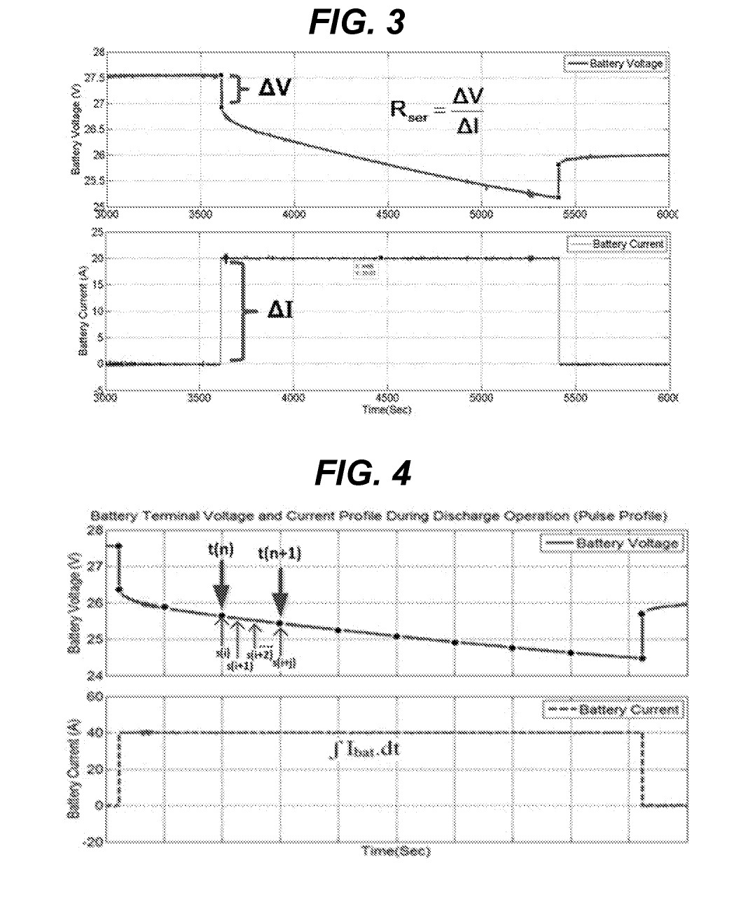

To explain the operation of Rs estimator 122 in more detail, FIG. 3 is an exemplary graph for estimating a series ohmic resistance (Rs) of a battery by using a voltage and current profile of a discharging operation. As shown in FIG. 3, battery voltage (V, measured in volts and corresponding to voltage 114) and battery current (I, measured in amperes or A, corresponding to current 116) are sampled over time. When a discharging operation begins, an instantaneous voltage drop ΔV_{bat} and a battery current ΔI_{bat} can be measured. Since these changes can be directly measured from the samples, the series ohmic resistance (Rs) can be estimated using an application of Ohm's law:

$${R}_{s} = \frac{Δ {V}_{bat}}{Δ {I}_{bat}} \qquad Equation 1$$

Taking the battery voltage at the instant of discharge as corresponding to OCV, then the Rs estimated above represents the Rs for that OCV (SoC). Thus, a temperature coefficient can be determined based on this relationship:

R_{S}=f(a₀,SoC) Equation 2

wherein the temperature coefficient a₀=f(T, SoH), where T is the temperature of the battery and SoH is the state of health of the battery. Assuming a battery at T=ambient temperature and SoH=100% health (no battery wear), a₀=1. Since this estimation relies on OCV, or rested open circuit voltage, the temperature coefficient a₀ may be updated each time a discharge operation occurs from a rested battery condition. Thus, an initial estimated Rs value can be output from Rs estimator 122.

### Battery Model Parameter (R₀, C₀) Estimation

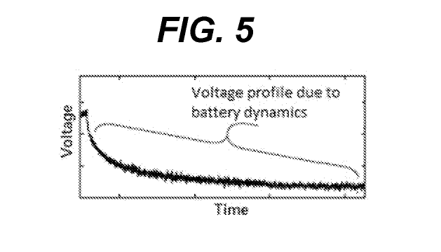

Continuing with the operation of R₀, C₀ estimator 124, referring to FIG. 4, FIG. 4 is an exemplary graph for estimating model parameters of a battery by using a voltage and current profile of a discharging operation. As discussed above, the sampling frequency does not need to correspond directly to the estimation update frequency. Thus, at each time s(i), s(i+1), s(i+2) . . . s(i+j), a new sample 112 may be sampled from battery pack 160. Accordingly, for each update at time t(n), j samples may be taken. The sampling frequency j and the updating frequency or time between t(n) and t(n+1) may be set according to, for example, battery operation characteristics, application sample data size and granularity requirements, and memory constraints. For example, if 40 voltage samples are a baseline minimum sample size requirement to accurately estimate the model parameters, then the updating frequency can be set to 2 seconds when the sampling frequency is set to 50 ms to provide the required 40 voltage samples per update.

The voltage drop observed during the discharge operation in FIG. 4 is due to a combination of ohmic resistance, charge delivering phenomena, and diffusion phenomena. However, it can be seen in FIG. 4 that the voltage drop between two estimation points, e.g. t(n) and t(n+1), appears to be almost linear. One reason is that the SoC-OCV relation is almost linear for lead acid battery voltage dropped per Ah of charge delivered, which remains constant throughout the SoC operating range. Another reason is that the resistance changes (increases) due to the discharge operation, which may be due to a linear IR₀ drop. The voltage profile between instants t(n) and t(n+1) can be given by the following equations:

$$\begin{matrix}V ( t ) = I ( t ) \cdot Δ {R}_{S} ( {SoC}_{Ah} ) + I ( t ) \cdot {R}_{0} \cdot {exp}^{\frac{- dt}{τ}} + {{a}_{1} ( I ( t ) )}^{K} dt & Equation 3 \\ Δ {R}_{S} ( {SoC}_{Ah} ) = {R}_{S} ( {SoC}_{Ah ( i + 1 )} ) - {R}_{S} ( {SoC}_{Ah ( i )} ) & Equation 4\end{matrix}$$

### Wherein:

V(t) is battery voltage at time t
I(t) is battery current at time t
ΔR_{S}(SoC_{Ah(i)}) is a series ohmic resistance estimated based on SoC using the Coulomb Counting technique at the ith sample instant.
R₀ is charge transfer resistance
dt is the updating interval “t(n+1)−t(n)”
τ=R₀·C₀ (RC time constant)
a₁=f(ΔV,Q_{P})=a constant representing voltage drop per Ah delivered as a function of Peukert's constant.
Q_{P}=I^{K}·t=Peukert's capacity (Ah capacity of battery when discharged at 1A)
K=Peukert's exponent

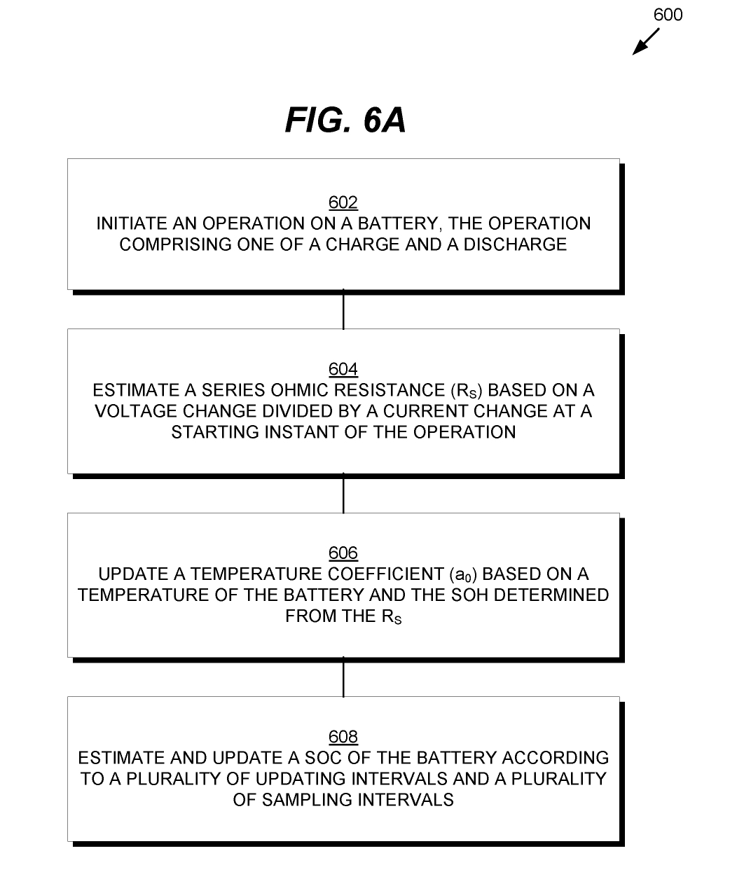

Since the aim is to estimate the values of R₀ and C₀ for a particular battery, the effects of charge delivering phenomena and linear IR_{S} drop are separated to focus on the effects of battery dynamics. Referring to FIG. 5, FIG. 5 is an exemplary graph of a battery voltage curve demonstrating a voltage profile due to battery dynamics. The voltage profile of FIG. 5 is given by the following equation:

$$\begin{matrix}{V}_{0} ( t ) = I ( t ) \cdot {R}_{0} \cdot {exp}^{\frac{- dt}{τ}} \\ = V ( t ) - I ( t ) \cdot Δ {R}_{S} ( {SoC}_{Ah} ) - \\ {{a}_{1} ( I ( t ) )}^{K} dt\end{matrix} \qquad Equation 5$$

Thus, referring back to FIG. 4, for each sample s(i), s(i+1), s(i+2) . . . s(i+j) acquired between t(n) and t(n+1), a corresponding voltage V₀(t) can be calculated using the above equation. The voltage curve V₀(t) can then be compared with the exponential term “I(t)·R₀·exp(t/τ)” to compute the battery parameters R₀ and C₀. Thus, R₀, C₀ estimator 124 can update R₀ and C₀ after time t(n+1) based on the samples gathered from t(n) to t(n+1).

### SoC Estimation Using Optimal Estimator and 1-RC Model

With the outputs of Rs estimator 122 and R₀, C₀ estimator 124 now available, attention can be turned to the working of SoC/SoH estimator 126. Specifically, SoC/SoH estimator 126 utilizes an optimal estimator to estimate the SoC of battery pack 160. The optimal estimator may be recursive and may utilize an Extended Kalman Filtering (EKF) to eliminate error due to measurement noise and process noise. The particular optimal estimator described herein uses a 1-RC model for battery pack 160.

The optimal estimator models the parameters of the battery, including unknown parameters, in its state description, allowing the optimal estimator to estimate a present value of a time varying dynamic system. First, in a prediction step or time update, the optimal estimator predicts the value of the present state, which thereby includes a system output and error covariance. Second, in a correction step or measurement update, the estimated system output is compared with actual physical system output, allowing the state estimate and error covariance to be corrected. An example space-state model of a system is provided below:

xₖ=Aₖ*xₖ₋₁+Bₖ*Uₖ+wₖ Equation 6

yₖ=Cₖ*xₖ+Dₖ*uₖ+vₖ Equation 7

For initialization, k=0:

Initial state, xₕ₀⁺=E[x₀]

Error Covariance P₀=E[(x₀−xₕ₀⁺)(x₀−xₕ₀⁺)^{T}]

For compute, k=1:

State estimate time update: xₕₖ⁻=Aₖ*xₖ₋₁⁺+Bₖ*uₖ (Eq. 8)

Error Covariance time update: Pₖ⁻=Aₖ*Pₖ₋₁⁺*Aₖ^{T}+Σ_{w} (Eq. 9)

Kalman gain Matrix: Lₖ=Pₖ⁻*Cₖ^{T}*(Cₖ*Pₖ⁻*Cₖ^{T}+Σᵥ)⁻¹ (Eq. 10)

System output estimate: yₖ⁻=C*xₕₖ⁻+D*uₖ (Eq. 11)

State Estimate Measurement update: xₕₖ⁺=xₕₖ⁻+Lₖ*[yₖ−yₖ⁻] (Eq. 12)

Error Covariance Measurement update: Pₖ⁺=(I−Lₖ*Cₖ)*Pₖ⁻ (Eq. 13)
Where:
wₖ—Process Noise
vₖ—Measurement Noise
Σ_{w}—Process noise covariance matrix
Σᵥ—Measurement noise covariance matrix

A filter equation for the battery system is as follows:

$$\begin{matrix} State Equation & \\ [ \begin{matrix}{SoC}_{( t )} \\ {V}_{0 ( t )}\end{matrix} ] = [ \begin{matrix}1 & 0 \\ 0 & 1 - ( \frac{dt}{{R}_{0 ( t )} * {C}_{0 ( t )}} )\end{matrix} ] [ \begin{matrix}{SoC}_{( t - 1 )} \\ {V}_{0 ( t - 1 )}\end{matrix} ] + [ \begin{matrix}\frac{- dt}{Q} \\ \frac{- dt}{{C}_{0 ( t )}}\end{matrix} ] [ {I}_{Bat ( t )} ] & Equation 14 \\ Output Equation & \\ {V}_{Bat ( t )} = {V}_{OC} ( {SoC}_{( t )} ) - {V}_{0 ( t )} - [ {I}_{Bat ( t )} * {R}_{s} ) \\ where \text{:} \\ {A}_{( t )} = [ \begin{matrix}1 & 0 \\ 0 & 1 - ( \frac{dt}{{R}_{0 ( t )} * {C}_{0 ( t )}} )\end{matrix} ] \\ {B}_{( t )} = [ \begin{matrix}\frac{- dt}{Q} \\ \frac{- dt}{{C}_{0 ( t )}}\end{matrix} ] \\ {C}_{( t - 1 )} = [ 1 - 1 ] \\ {D}_{( t - 1 )} = [ - {R}_{s} ] \\ {u}_{( t )} = {I}_{( t )} & Equation 15\end{matrix}$$

### SoH Estimation Using Nominal Capacity and SoC

After SoC is calculated using the optimal estimator described above, the SoC value may be updated in values 128 after time t(n+1). Conventionally, SoH may be measured by sampling a particular parameter, such as cell impedance, and comparing the sampled parameter to a control parameter measured from a fresh or new battery. This may require the computation of OCV, which requires the battery to start in a resting state. However, in an online environment where the battery is in use, it may be difficult to reach a resting state as the battery may be constantly charging and discharging.

Accordingly, an online approach to estimating and updating SoH is necessary. One approach is described in US Patent Application Publication Number US 2013/0138369, titled “METHOD AND APPARATUS FOR ONLINE DETERMINATION OF BATTERY STATE OF CHARGE AND STATE OF HEALTH”, hereby incorporated by reference as if contained entirely herein. To summarize the approach, since the full capacity of a battery is a good indicator of the battery's SoH, the present full capacity can be estimated online (based on the estimated SoC) and compared with a nominal capacity of a fresh or new battery to determine the SoH. Thus, once the SoC, the battery current, and the duration of the last charging or discharging operation is known in values 128, then the SoH may be estimated as follows:

Q_{full}=f(SoC,I,t_{dis/ch}) (Equation 16)

SoH=f(Q_{full},Qₙₒₘ) (Equation 17)

where Q_{full} is the estimated full capacity of the battery and Qₙₒₘ is the nominal capacity of the battery when new.

### SoC Estimation Flowchart

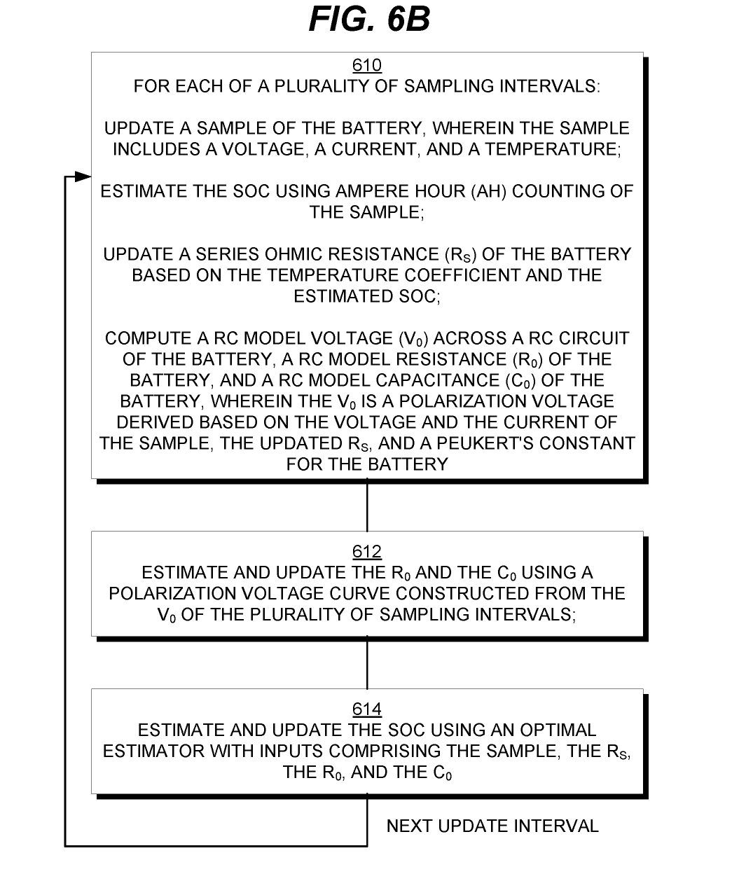

Now that the details of each of the estimators have been described, it may be helpful to review an exemplary process that puts all of the estimators in context. FIG. 6A and FIG. 6B are flowcharts of an exemplary method for online estimation of battery parameters for determining a State-of-Charge (SoC) of a battery. Process 600 of FIG. 6A includes block 602, block 604, block 606, and block 608.

At block 602 of process 600, processor 121 begins by initiating an operation on battery pack 160, the operation comprising one of a charge and a discharge. As discussed above, in an automotive context, a charge operation may be initiated in response to regenerative braking or when power received from generator connected to engine shaft, and a discharge operation may be initiated in response to pressure on an acceleration pedal. Thus, besides battery power management, processor 121 may also control the main functions of an automobile, such as an electric or hybrid vehicle.

At block 604 of process 600, processor 121 estimates a series ohmic resistance (R_{S}) based on a voltage change divided by a current change at a starting instant of the operation. Rs estimator 122 may therefore request a sample 112 from data sampling module 110 immediately before and after the operation in block 602 is initiated. Thus, a change in voltage 114 and current 116 from battery pack 160 can be ascertained, and R_{S} can be determined using an Ohm's law, as discussed above in conjunction with Equation 1 and FIG. 3.

At block 606 of process 600, processor 121 updates a temperature coefficient (a₀) based on a temperature of the battery and the SoH determined from the R_{S}. As discussed above in conjunction with Equation 2, this can be estimated using the R_{S} from block 604, temperature 118 from sample 112, and the OCV, or a rested open circuit voltage read as the initial voltage sample from block 604. Thus, after determining R_{S}, Rs estimator 122 may continue to determine a₀ as necessary.

At block 608 of process 600, processor 121 estimates and updates a SoC of battery pack 160 according to a plurality of updating intervals and a plurality of sampling intervals. Thus, Rs estimator 122, R₀C₀ estimator 124, and SoC/SoH estimator 126 may process sample sets to update values 128, including the SoC of battery pack 160, in real-time.

Turning to FIG. 6B, FIG. 6B shows in further detail an updating interval for block 608 of FIG. 6A. Thus, block 608 may repeat block 610, block 612, and block 614 for each of a plurality of updating intervals. As discussed above, the sampling intervals may occur more frequently than the updating intervals such that each updating interval has a minimum sample size for accurate data estimation.

Block 610 is carried out for each of a plurality of sampling intervals. Processor 121 may begin by requesting data sampling module 110 to update sample 112 of battery pack 160, wherein sample 112 includes voltage 114, current 116, and temperature 118.

Block 610 continues with processor 121 estimating the SoC of battery pack 160 using ampere hour (Ah) counting of sample 112. As discussed above, during a sampling instant t between the updating instants t(n) and t(n+1), the voltage and current profiles can be estimated using Equation 3 and Equation 4. Thus, the SoC of battery pack 160 can be updated after each sampling interval using Coulomb Counting or Ah counting:

SoCcc(i)=SoCcc(i−1)−(I(t)*dt/Q) (Equation 18)

Block 610 continues with processor 121 updating a series ohmic resistance (R_{S}) of the battery based on the temperature coefficient (a₀) and the estimated SoC (SoCcc(i) from above). Thus, after each sampling interval, R_{S} can be updated as follows:

R_{S}=f(a₀,SoC(i)) (Equation 19)

Block 610 continues with processor 121 computing a RC model voltage (V₀) across a RC circuit of battery pack 160, a RC model resistance (R₀) of the battery, and a RC model capacitance (C₀) of the battery, wherein the V₀ is a polarization voltage derived based on the voltage 114 and the current 116 of the sample 112, the updated R_{S}, and a Peukert's constant for the battery. The specific processing is described above under the heading “Battery model parameter (R₀, C₀) estimation”.

Block 612 continues with processor 121 estimating and updating the R₀ and the C₀ using a polarization voltage curve constructed from the V₀ of the plurality of sampling intervals. After the completion of block 610, V₀ values for each of the sampling points are available. Thus, as discussed above, Equation 5 can be utilized to estimate and update the battery model parameters, including R₀ and C₀.

Block 614 continues with processor 121 estimating and updating the SoC using an optimal estimator with inputs comprising sample 112 and values 128 including the R_{S}, the R₀, and the C₀. The specific processing of the optimal estimator is described above under the heading “SoC Estimation using Optimal Estimator and 1-RC Model”. After the optimal estimator completes, a newly updated SoC value is placed in values 128. Thus, the SoC value for battery pack 160 can be accurately updated online after each updating interval. Since the processing complexity and memory requirement for each updating interval is relatively low using the above described mathematical approach with a fixed size sample set, the estimating and updating of the SoC can be done in real-time during each update interval.

As discussed above, to update the SoH online, the SoC can be compared to the SoC of a nominal battery, as discussed above in the heading “SoH Estimation using Nominal Capacity and SoC”. Thus, both SoC and SoH can be accurately updated in an online context to, for example, optimize battery usage, avoid deep discharge operations, provide maintenance warnings, and record diagnostics.

It should be understood, of course, that the foregoing relates to exemplary embodiments of the invention and that modifications may be made without departing from the spirit and scope of the invention as set forth in the following claims.

We claim:

1. A method for online estimation of battery model parameters for determining a State-of-Charge (SoC) of a battery, the method comprising:
initiating an operation on the battery, the operation comprising one of a charge and a discharge;
estimating a series ohmic resistance (R_{S}) based on a voltage change divided by a current change at a starting instant of the operation;
updating a temperature coefficient (a₀) based on a temperature of the battery and the SoH determined from the R_{S}; and
performing, until the operation on the battery is completed:
for each of a plurality of updating intervals:
for each of a plurality of sampling intervals:
updating a sample of the battery, wherein the sample includes a voltage, a current, and a temperature;
estimating the SoC using ampere hour (Ah) counting of the sample;
updating a series ohmic resistance (R_{S}) of the battery based on the temperature coefficient and the estimated SoC;
computing a RC model voltage (V₀) across a RC circuit of the battery, a RC model resistance (R₀) of the battery, and a RC model capacitance (C₀) of the battery, wherein the V₀ is a polarization voltage derived based on the voltage and the current of the sample, the updated R_{S}, and a Peukert's constant for the battery;
estimating and updating the R₀ and the C₀ using a polarization voltage curve constructed from the V₀ of the plurality of sampling intervals; and
estimating and updating the SoC using an optimal estimator with inputs comprising the sample, the R_{S}, the R₀, and the C₀;
wherein the method is performed by one or more processors.

2. The method of claim 1, wherein the method further comprises:
completing the operation on the battery;
estimating a full capacity of the battery based on the SoC, a current of the operation, and a duration of the operation; and
estimating a State-of-Health (SoH) of the battery using the estimated full capacity of the battery and a nominal capacity of the battery.

3. The method of claim 1, wherein the optimal estimator utilizes an Extended Kalman Filter (EKF).

4. The method of claim 1, wherein the plurality of sampling intervals occur more frequently than the plurality of updating intervals.

5. The method of claim 1, wherein the estimating and the updating of the SoC is performed in real-time during each of the plurality of updating intervals.

6. The method of claim 1, wherein the V₀, the R₀, and the C₀ are computed for a 1-RC model of the battery.

7. The method of claim 1, further comprising:
switching a power source for a load between the battery and an engine, wherein the switching is based on the estimated and updated SoC.

8. An apparatus providing online estimation of battery model parameters for determining a State-of-Charge (SoC) of a battery, the apparatus comprising one or more processors configured to:
initiate an operation on the battery, the operation comprising one of a charge and a discharge;
estimate a series ohmic resistance (R_{S}) based on a voltage change divided by a current change at a starting instant of the operation;
update a temperature coefficient (a₀) based on a temperature of the battery and the SoH determined from the R_{S};
perform, until the operation on the battery is completed:
for each of a plurality of updating intervals:
for each of a plurality of sampling intervals:
update a sample of the battery, wherein the sample includes a voltage, a current, and a temperature;
estimate the SoC using ampere hour (Ah) counting of the sample;
update a series ohmic resistance (R_{S}) of the battery based on the temperature coefficient and the estimated SoC;
compute a RC model voltage (V₀) across a RC circuit of the battery, a RC model resistance (R₀) of the battery, and a RC model capacitance (C₀) of the battery, wherein the V₀ is a polarization voltage derived based on the voltage and the current of the sample, the updated R_{S}, and a Peukert's constant for the battery;
estimate and update the R₀ and the C₀ using a polarization voltage curve constructed from the V₀ of the plurality of sampling intervals;
estimate and update the SoC using an optimal estimator with inputs comprising the sample, the R_{S}, the R₀, and the C₀.

9. The apparatus of claim 8, wherein the one or more processors are further configured to:
complete the operation on the battery;
estimate a full capacity of the battery based on the SoC, a current of the operation, and a duration of the operation; and
estimate a State-of-Health (SoH) of the battery using the estimated full capacity of the battery and a nominal capacity of the battery.

10. The apparatus of claim 8, wherein the optimal estimator utilizes an Extended Kalman Filter (EKF).

11. The apparatus of claim 8, wherein the plurality of sampling intervals occur more frequently than the plurality of updating intervals.

12. The apparatus of claim 8, wherein the estimating and the updating of the SoC is performed in real-time during each of the plurality of updating intervals.

13. The apparatus of claim 8, wherein the V₀, the R₀, and the C₀ are computed for a 1-RC model of the battery.

14. The apparatus of claim 8, wherein the one or more processors are further configured to:
switch a power source for a load between the battery and an engine, wherein the switching is based on the estimated and updated SoC.

15. A computer readable non-transitory medium providing online estimation of battery model parameters for determining a State-of-Charge (SoC) of a battery, the computer readable non-transitory medium including one or more instructions that, when executed by one or more processors, causes:
initiating an operation on the battery, the operation comprising one of a charge and a discharge;
estimating a series ohmic resistance (R_{S}) based on a voltage change divided by a current change at a starting instant of the operation;
updating a temperature coefficient (a₀) based on a temperature of the battery and the SoH determined from the R_{S};
performing, until the operation on the battery is completed:
for each of a plurality of updating intervals:
for each of a plurality of sampling intervals:
updating a sample of the battery, wherein the sample includes a voltage, a current, and a temperature;
estimating the SoC using ampere hour (Ah) counting of the sample;
updating a series ohmic resistance (R_{S}) of the battery based on the temperature coefficient and the estimated SoC;
computing a RC model voltage (V₀) across a RC circuit of the battery, a RC model resistance (R₀) of the battery, and a RC model capacitance (C₀) of the battery, wherein the V₀ is a polarization voltage derived based on the voltage and the current of the sample, the updated R_{S}, and a Peukert's constant for the battery;
estimating and updating the R₀ and the C₀ using a polarization voltage curve constructed from the V₀ of the plurality of sampling intervals;
estimating and updating the SoC using an optimal estimator with inputs comprising the sample, the R_{S}, the R₀, and the C₀.

16. The computer readable non-transitory medium of claim 15, wherein the method further comprises:
completing the operation on the battery;
estimating a full capacity of the battery based on the SoC, a current of the operation, and a duration of the operation; and
estimating a State-of-Health (SoH) of the battery using the estimated full capacity of the battery and a nominal capacity of the battery.

17. The computer readable non-transitory medium of claim 15, wherein the optimal estimator utilizes an Extended Kalman Filter (EKF).

18. The computer readable non-transitory medium of claim 15, wherein the plurality of sampling intervals occur more frequently than the plurality of updating intervals.

19. The computer readable non-transitory medium of claim 15, wherein the estimating and the updating of the SoC is performed in real-time during each of the plurality of updating intervals.

20. The computer readable non-transitory medium of claim 15, wherein the V₀, the R₀, and the C₀ are computed for a 1-RC model of the battery.
